(19) United States
(12) Patent Application Publication
(10) Pub. No.: US 2013/0128464 A1
(43) Pub. Date: May 23, 2013

(54) RISER CARD

(71) Applicant: ASUSTEK COMPUTER INC., Taipei (TW)

(72) Inventors: Chien-Ying CHEN, TAIPEI (TW); I-Hsiang LIN, TAIPEI (TW)

(73) Assignee: ASUSTEK COMPUTER INC., TAIPEI (TW)

(21) Appl. No.: 13/678,558

(22) Filed: Nov. 16, 2012

Related U.S. Application Data
(60) Provisional application No. 61/560,813, filed on Nov. 17, 2011.

(51) Int. Cl. H05K 7/02; H05K 5/00; H05K 7/20

(52) U.S. Cl. CPC H05K 7/026; H05K 7/20; H05K 5/0026
USPC 361/721; 361/803; 361/752

(57) ABSTRACT

A riser card for connecting at least one high-speed signal card to a mainboard is provided. The high-speed signal card includes a first connecting portion and a second connecting portion. The riser card includes a circuit board, a plurality of slots, a connection terminal, a power supply module, and a supporting board. The slots include a first slot and a second slot disposed spaced apart on a first surface of the circuit board and connected to the first connecting portion and the second connecting portion respectively of the high-speed signal card. The connection terminal connects to the mainboard. The power supply module is fixed to a second surface of the circuit board by using the supporting board and supplies power to the high-speed signal card via the circuit board, so that the high-speed signal card is able to exchange data with the mainboard via the riser card.

### RELATED APPLICATIONS

This application claims priority to U.S. Provisional Application Ser. No. 61/560,813, filed Nov. 17, 2011, which is herein incorporated by reference.

### BACKGROUND

1. Technical Field

The present disclosure relates to a riser card and an electronic apparatus including the same.

2. Description of Related Art

With continued development in the fields of technology and information, computers are quite common electronic apparatuses. Desktop computers, notebook computers, and servers need to connect with peripheral equipment through various kinds of riser cards. For example, one type of riser card is an add-on card which is used to connect a host computer to peripheral equipment, so that the host computer can communicate with the peripheral equipment and perform control to enable the peripheral equipment to perform its functions. In a conventional electronic apparatus, many add-on cards (e.g., a video card, a sound card, a network interface card, a USB card, a memory card etc.) are typically plugged into a mainboard for increasing functions or enhancing efficiency.

PCI (Peripheral Component Interconnect) interface has become a bus standard for connecting mainboards with peripheral equipment in host computers. That is, add-on cards that are the most commonly used in host computers nowadays are PCI cards, and slots disposed on the mainboards are mostly PCI slots.

However, there are special add-on cards that are different from PCI cards in the market, an example of which are high-speed signal cards for disk control. If users want to use a special add-on card, they must either buy a mainboard having special slots adapted for the special add-on card, or buy a special add-on card that is compatible with PCI slots. Both these options cause inconvenience to users. Moreover, even if users buy special add-on cards that are compatible with PCI slots, one PCI slot can only be plugged into by one of the special add-on cards, and so the expandability is not good.

### SUMMARY

In order to solve the problems of the prior art, the disclosure provides an improved riser card. The riser card can be connected to a high-speed signal card having a special interface and can connect to a PCI slot on a mainboard with its connection terminal, so that the signals of the high-speed signal card can be transmitted to the mainboard via the riser card.

According to an embodiment of the disclosure, a riser card is used to connect at least one high-speed signal card. The high-speed signal card includes a plurality of connecting portions. The riser card includes a first circuit board, a plurality of slots, and a connection terminal. The first circuit board has a first surface and a second surface that are opposite to each other. The slots are disposed spaced apart on a first surface. Each of the slots is connected to a corresponding connecting portion of the high-speed signal card. The connection terminal connects to a mainboard.

In an embodiment of the disclosure, the first circuit board has a through hole. The through hole communicates the first surface and the second surface. The through hole is located among the slots.

In an embodiment of the disclosure, the riser card further includes a fixing bracket. The fixing bracket is fixed to the first circuit board.

In an embodiment of the disclosure, the fixing bracket is fastened to the first circuit board by a screw.

In an embodiment of the disclosure, the riser card further includes a plurality of the slots disposed spaced apart on the first surface and respectively connected to a plurality of the high-speed signal cards.

In an embodiment of the disclosure, the riser card further includes a supporting board and a power supply module. The supporting board is fixed to the second surface. The power supply module is fixed to the supporting board and supplies power to the high-speed signal card via the first circuit board.

In an embodiment of the disclosure, the power supply module includes a battery and a battery backup unit. The battery is fixed to the supporting board and supplies power to the high-speed signal card via the first circuit board. The battery backup unit is fixed to the supporting board and electrically connected to the first circuit board and the battery.

In an embodiment of the disclosure, the connection terminal is a PCI connection terminal.

The disclosure further provides an improved electronic apparatus.

According to an embodiment of the disclosure, the electronic apparatus includes a casing, a mainboard, a riser card, and at least one high-speed signal card. The mainboard is disposed in the casing. The riser card includes a first circuit board, a plurality of slots, a connection terminal, and a fixing bracket. The first circuit board has a first surface, a second surface, and a through hole. The through hole communicates the first surface and the second surface. The slots are disposed spaced apart on the first surface. The connection terminal connects to the mainboard. The fixing bracket is fixed to the first circuit board and the casing. The high-speed signal card includes a plurality of connecting portions. Each of the connecting portions connects to a corresponding slot of the riser card.

In an embodiment of the disclosure, the slots include a first slot and a second slot. The through hole is located between the first slot and the second slot. The connecting portions include a first connecting portion and a second connecting portion. The first connecting portion and the second connecting portion respectively connect to the first slot and the second slot.

In an embodiment of the disclosure, the high-speed signal card further includes a second circuit board and a heat sink. The first connecting portion and the second connecting portion are located spaced apart at an edge of the second circuit board. The heat sink is fixed to the second circuit board and extends from the edge of the second circuit board to a section between the first connecting portion and the second connecting portion. The heat sink is located between the first slot and the second slot and partially accommodated in the through hole.

In an embodiment of the disclosure, the high-speed signal card further includes a first fixing plate. The first fixing plate is clamped between the second circuit board and the heat sink and fastened to the first circuit board by a screw.

In an embodiment of the disclosure, the high-speed signal card further includes a second fixing plate. The second fixing plate is fixed to the heat sink and has a first engaging portion. A sidewall of the first slot has a second engaging portion. The first engaging portion is engaged with the second engaging portion.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a perspective view of a riser card and a high-speed signal card assembled to a mainboard in an electronic apparatus according to an embodiment of the disclosure;

FIG. 2 is an exploded view of the riser card and the high-speed signal card in FIG. 1;

FIG. 3 is another exploded view of the riser card and the high-speed signal card in FIG. 1; and

FIG. 4 is a perspective view of a riser card and two high-speed signal cards assembled to a mainboard in an electronic apparatus according to another embodiment of the disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

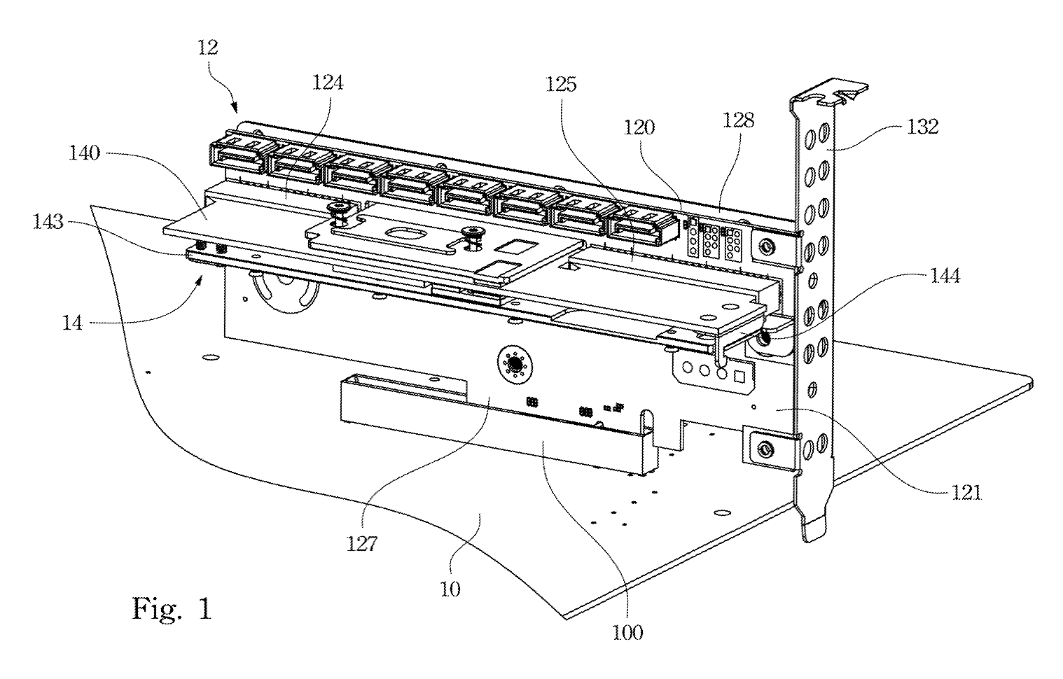

FIG. 1 is a perspective view of a riser card 12 and a high-speed signal card 14 assembled to a mainboard 10 in an electronic apparatus (not shown) according to an embodiment of the disclosure. The electronic apparatus has a housing (not shown) and the mainboard 10 which is disposed in the housing, and the riser card 12 is detachably assembled to the mainboard 10. The riser card 12 includes a fixing bracket 132. The riser card 12 is detachably disposed on the mainboard 10, so as to be electrically connected to the mainboard 10. The high-speed signal card 14 is detachably connected to the riser card 12, so as to transmit signals to the mainboard 10 via the riser card 12. In other words, the high-speed signal card 14 can exchange information with the mainboard 10 via the riser card 12.

Furthermore, the fixing bracket 132 of the riser card 12 is fixed to the housing of the electronic apparatus, so as to further secure the riser card 12 that is disposed on the mainboard 10 to the housing. In this embodiment, a host computer is used as an example of the electronic apparatus, but the disclosure is not limited in this regard. Moreover, in addition to the mainboard 10, many electronic components (for example, a fan, a hard drive, a CD-ROM drive, a power supply, etc. which are not shown) having different functions can be disposed in the housing.

As shown in FIG. 1, the mainboard 10 of the electronic apparatus includes a PCI (Peripheral Component Interconnect) slot 100. It should be pointed out that the PCI slot 100 referred to in the disclosure may be a common slot with a PCI interface or with a PCI-E (PCI Express) interface. Moreover, in addition to the PCI slot 100, many electronic components or slots (for example, a CPU, a north bridge, a south bridge, integrated peripherals, a BIOS, a power outlet, etc. which are not shown) can be disposed on the mainboard 10.

As shown in FIG. 1, the riser card 12 includes a connection terminal 127. It should be pointed out that the connection terminal 127 referred to in the disclosure may be a common PCI connection terminal (i.e., metal signal pins) or a PCI-E connection terminal, but the disclosure is not limited in this regard. After the riser card 12 and the high-speed signal card 14 are completely assembled the riser card 12 can connect to the PCI slot 100 of the mainboard 10 using the connection terminal 127, as shown in FIG. 1.

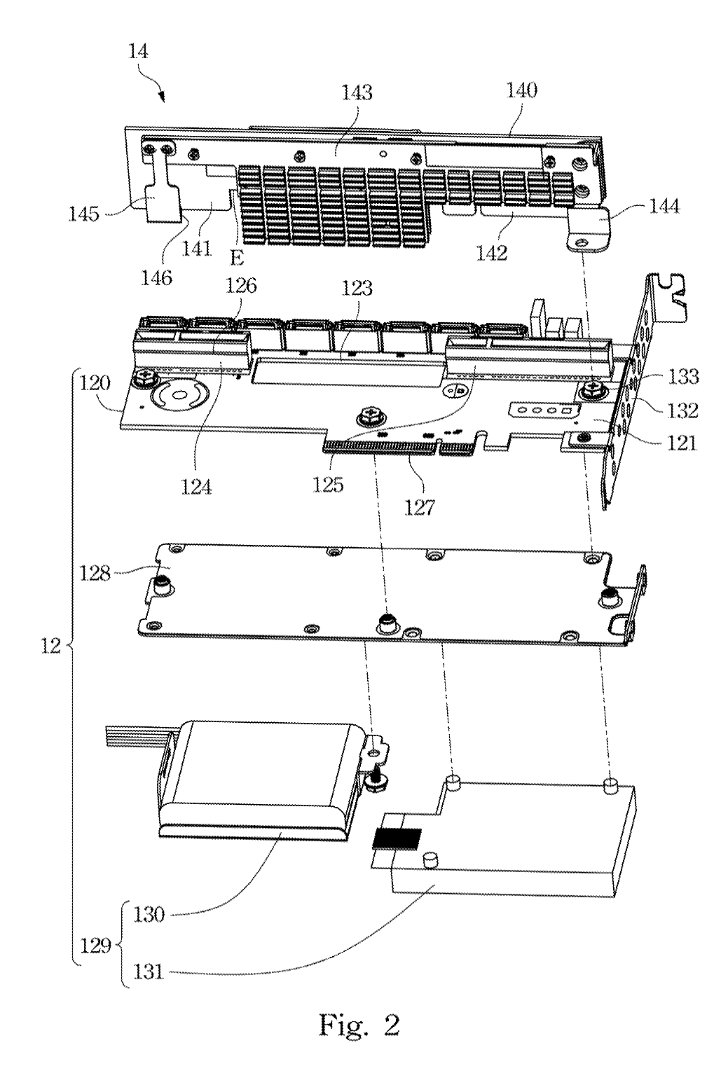

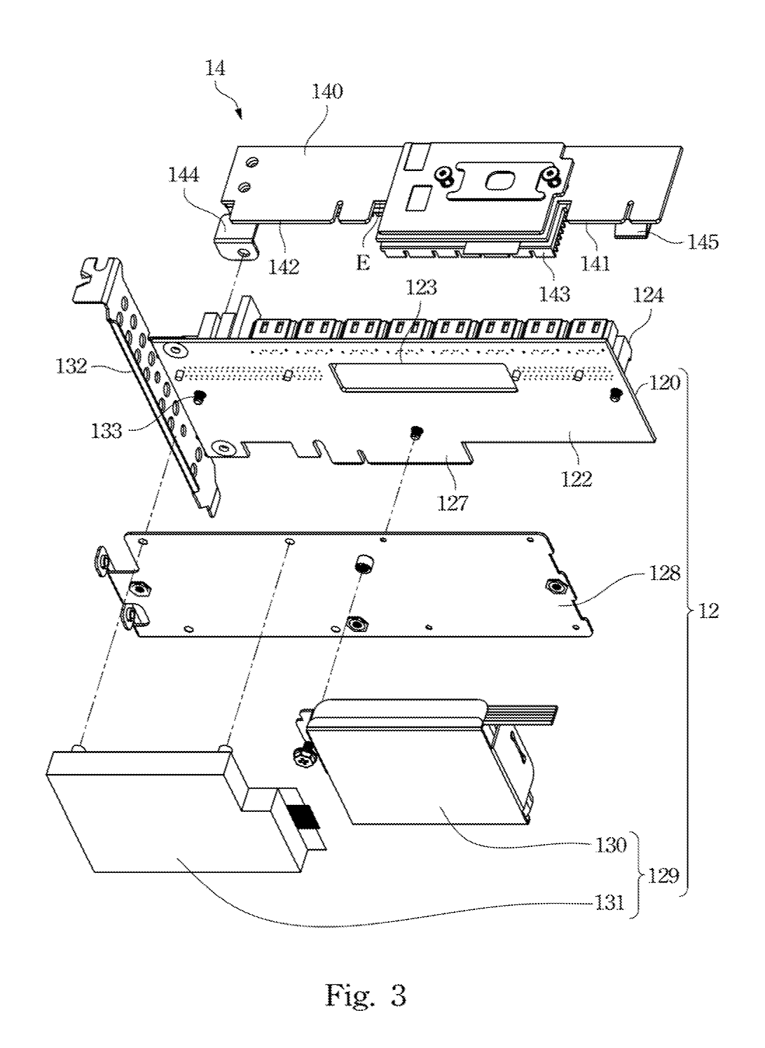

FIG. 2 is an exploded view of the riser card 12 and the high-speed signal card 14 in FIG. 1. FIG. 3 is another exploded view of the riser card 12 and the high-speed signal card 14 in FIG. 1.

As shown in FIG. 2 and FIG. 3, the riser card 12 includes a first circuit board 120, a plurality of slots, the connection terminal 127, a supporting board 128, and a power supply module 129. The first circuit board 120 of the riser card 12 has a first surface 121, a second surface 122, and a through hole 123. The first surface 121 and the second surface 122 of the first circuit board 120 are opposite to each other. The through hole 123 of the first circuit board 120 communicates the first surface 121 and the second surface 122.

The slots of the riser card 12 are disposed spaced apart on the first surface 121 of the first circuit board 120. That is, each of the slots of the riser card 12 is disposed at a particular position on the first surface 121, and the slots do not structurally connect to each other. In the embodiment of the disclosure, the slots include a first slot 124 and a second slot 125. The first slot 124 and the second slot 125 are disposed spaced apart on the first surface 121 of the first circuit board 120. The through hole 123 of the first circuit board 120 is located between the first slot 124 and the second slot 125.

The supporting board 128 of the riser card 12 is fixed to the second surface 122 of the first circuit board 120. The power supply module 129 of the riser card 12 is fixed to the supporting board 128 and electrically connected to the first circuit board 120. The supporting board 128 of the riser card 12 is fixed to the second surface 122 of the first circuit board 120 and the power supply module 129 is fixed to the supporting board 128 using screws, welds, rivets, or other mechanical means.

Furthermore, as shown in FIG. 2, the high-speed signal card 14 includes a first connecting portion 141 and a second connecting portion 142. The first connecting portion 141 and the second connecting portion 142 of the high-speed signal card 14 are capable of respectively connecting to the first slot 124 and the second slot 125 of the riser card 12. That is, the first slot 124 and the second slot 125 of the riser card 12 are particularly designed to be respectively connected to the first connecting portion 141 and the second connecting portion 142 of the high-speed signal card 14. With this configuration, the power supply module 129 of the riser card 12 can supply power to the high-speed signal card 14 via the first circuit board 120.

In an embodiment of the disclosure, the high-speed signal card 14 can be an add-on card with a special interface different from PCI interface. For example, the high-speed signal card 14 may be a RAID (Redundant Array of Inexpensive Disks) card capable of transmitting signals at a high speed, but the disclosure is not limited in this regard.

In an embodiment of the disclosure, the power supply module 129 of the riser card 12 includes a battery 130 and a battery backup unit 131. The battery 130 of the power supply module 12 is fixed to the supporting board 128 and supplies power to the high-speed signal card 14 via the first circuit board 120. The battery backup unit 131 is fixed to the supporting board 128 and electrically connected to the first circuit board 120 and the battery 130.

When the power supply of the mainboard 10 is suddenly interrupted (e.g., when the power supply is damaged), the power supply module 129 on the riser card 12 can continuously supply power to the high-speed signal card 14 through the battery backup unit 131, thereby temporarily preserving information in the high-speed signal card 14.

As shown in FIG. 2 and FIG. 3, the high-speed signal card 14 further includes a second circuit board 140 and a heat sink 143. The first connecting portion 141 and the second connecting portion 142 of the high-speed signal card 14 are located spaced apart at an edge E of the second circuit board 140. The heat sink 143 of the high-speed signal card 14 is fixed to the second circuit board 140 and extends from the edge E to a section between the first connecting portion 141 and the second connecting portion 142. The heat sink 143 dissipates the heat generated by the second circuit board 140 into the air.

After the first connecting portion 141 and the second connecting portion 142 of the high-speed signal card 14 are respectively connected to the first slot 124 and the second slot 125 of the riser card 12, the heat sink 143 of the high-speed signal card 14 is located between the first slot 124 and the second slot 125 and partially accommodated in the through hole 123 of the first circuit board 120. The heat sink 143 of the high-speed signal card 14 can also be fixed to the second circuit board 140 by screws, welds, rivets, or other mechanical means.

In other words, when the high-speed signal card 14 is connected to the riser card 12, the edge E of the second circuit board 140 is adjacent to the first circuit board 120 of the riser card 12, and the heat sink 143 of the high-speed signal card 14 extends toward the first circuit board 120 of the riser card 12. Since the heat sink 143 extends from the edge E of the second circuit board 140, the first circuit board 120 of the riser card 12 is designed with the through hole 123 formed therein for accommodating the heat sink 143. As a result of this configuration, the high-speed signal card 14 and the riser card 12 occupy a small volume after being assembled to each other, so as to improve the space utilization in the housing of the electronic apparatus.

As shown in FIG. 2 and FIG. 3, the high-speed signal card 14 further includes a first fixing plate 144 and a second fixing plate 145. The first fixing plate 144 of the high-speed signal card 14 is clamped between the second circuit board 140 and the heat sink 143. The second fixing plate 145 of the high-speed signal card 14 is fixed to the heat sink 143 and has a first engaging portion 146. A side wall of the first slot 124 of the first circuit board 120 correspondingly has a second engaging portion 126. It is noted that the position of the heat sink 143 to which the second fixing plate 145 of the high-speed signal card 14 is fixed is adjacent to the first connecting portion 141 of the second circuit board 140.

After the first connecting portion 141 and the second connecting portion 142 of the high-speed signal card 14 are respectively connected to the first slot 124 and the second slot 125 of the riser card 12, the first fixing plate 144 of the high-speed signal card 14 can be fastened to the first circuit board 120 of the riser card 12 by a screw 133, and the first engaging portion 146 of the second fixing plate 145 can be engaged with the second engaging portion 126 on the sidewall of the first slot 124. Through such a configuration, the fixing strength between the high-speed signal card 14 and the riser card 12 can be enhanced. However, the disclosure is not limited in this regard.

In another embodiment of the disclosure, the first fixing plate 144 of the high-speed signal card 14 can be fixed to the second circuit board 140 and the riser card 12 or to the heat sink 143 and the riser card 12 using a weld, a rivet, or other mechanical means. The second fixing plate 145 of the high-speed signal card 14 can also be fixed to the heat sink 143 using a screw, a weld, a rivet, or the other mechanical means.

However, the disclosure is not limited in this regard. In another embodiment of the disclosure, the second fixing plate 145 of the high-speed signal card 14 can be directly fixed to the second circuit board 140. Moreover, in another embodiment of the disclosure, the second engaging portion 126 that is disposed at the sidewall of the first slot 124 of the first circuit board 120 in the above-described embodiment can instead be disposed at a sidewall of the second slot 125, and the position of the heat sink 143 to which the second fixing plate 145 of the high-speed signal card 14 is fixed can be changed to be adjacent to the second connecting portion 142 of the second circuit board 140. With this configuration, the fixing strength between the high-speed signal card 14 and the riser card 12 that are assembled to each other can also be enhanced.

As shown in FIG. 2 and FIG. 3, the screw 133 that is used to fasten the first fixing plate 144 of the high-speed signal card 14 to the first circuit board 120 of the riser card 12 also fastens the fixing bracket 132 to the first circuit board 120 of the riser card 12 and fastens the supporting board 128 to the first circuit board 120.

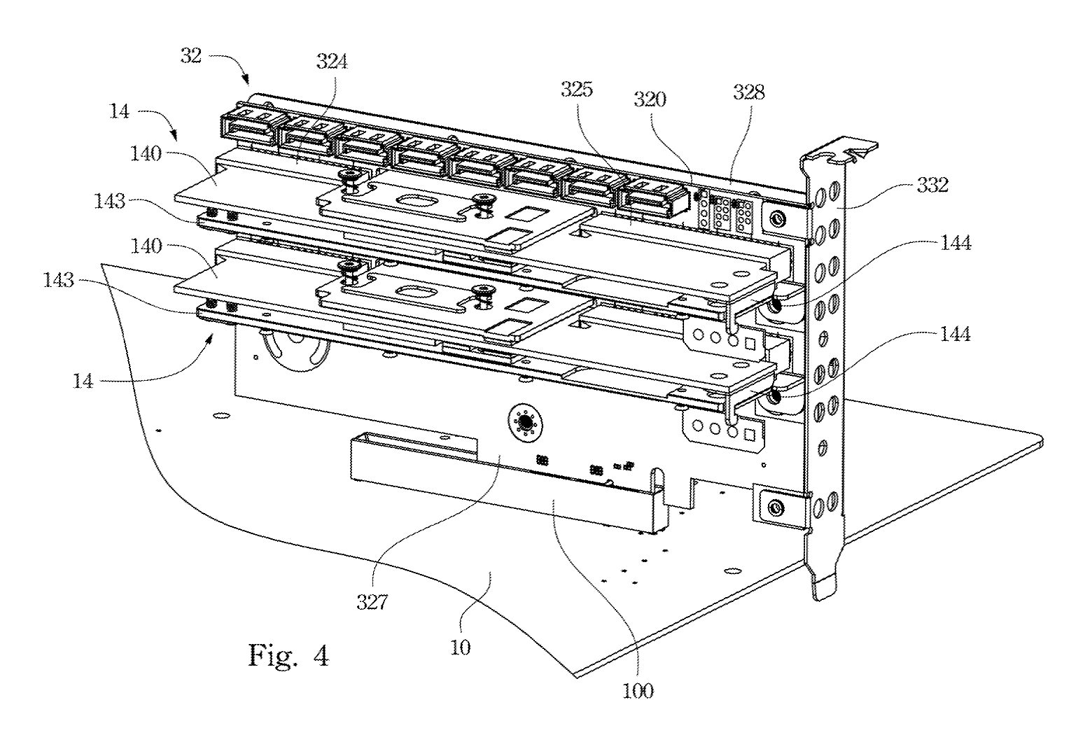

FIG. 4 is a perspective view of a riser card 32 and two high-speed signal cards 14 assembled to a mainboard 10 in an electronic apparatus according to another embodiment of the disclosure.

As shown in FIG. 4, the riser card 32 includes a first circuit board 320, a connection terminal 327, a supporting board 328, and a fixing bracket 332. The riser card 32 can be connected to a PCI slot 100 of the mainboard 10 by the connection terminal 327. Both of the supporting board 328 and the fixing bracket 332 of the riser card 32 are fixed to the first circuit board 320.

It should be pointed out that two sets of slots (i.e., two sets of a first slot 324 and a second slot 325) are disposed on the riser card 32 for two high-speed signal cards 14 to connect to, so that the expandability of the riser card 32 is greatly improved. However, the disclosure is not limited in this regard. In accordance with the concept of the embodiment, more than two sets of slots can also be disposed on the riser card 32 for more than two high-speed signal cards 14 to connect to.

Furthermore, with respect to the structures of the high-speed signal cards 14 and the manner in which the high-speed signal cards 14 are connected to and fixed to the first circuit board 320 of the riser card 32, reference can be made to the related descriptions of the riser card 12 and the high-speed signal card 14 in the above embodiment shown in FIG. 1 to FIG. 3. Therefore an explanation in this regard will not be repeated.

According to the foregoing recitations of the embodiments of the disclosure, it can be seen that the riser card can be connected to a high-speed signal card having a special interface and can connect to a PCI slot on a mainboard with its connection terminal, so that the signals of the high-speed signal card can be transmitted to the mainboard via the riser card. Therefore, the high-speed signal card having the special interface can also be applied to a mainboard without the special interface. That is, even if a user buys a mainboard having a PCI slot, the mainboard can use the high-speed signal card having the special interface via the riser card of the disclosure, and so it is not necessary for the user to buy high-speed signal cards that are compatible with the PCI slot.

Moreover, in some embodiments, the riser card of the disclosure has a plurality of slots having the special interface for a plurality of high-speed signal cards to connect to, while the riser card only occupies one PCI slot. As a result, the expandability can be greatly improved.

Furthermore, the riser card has a power supply module which can directly supply power to the high-speed signal card(s). Therefore, when the power supply of the mainboard is suddenly interrupted, the power supply module on the riser card can continuously supply power to the high-speed signal card(s), thereby temporarily preserving information in the high-speed signal card(s).

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fail within the scope of the following claims.

What is claimed is:

1. A riser card for connecting at least one high-speed signal card, the high-speed signal card comprising a plurality of connecting portions, the riser card comprising:
a first circuit board having a first surface and a second surface;
a plurality of slots disposed spaced apart on the first surface, each of the slots being connected to a corresponding connecting portion of the high-speed signal card; and
a connection terminal for connecting to a mainboard.

2. The riser card of claim 1, wherein the first circuit board has a through hole communicating the first surface and the second surface, and the through hole is located among the slots.

3. The riser card of claim 1, further comprising a fixing bracket fixed to the first circuit board.

4. The riser card of claim 1, further comprising a plurality of the slots disposed spaced apart on the first surface and respectively connected to a plurality of the high-speed signal cards.

5. The riser card of claim 1, further comprising:
a supporting board fixed to the second surface; and
a power supply module fixed to the supporting boa and supplying power to the high-speed signal card via the first circuit board.

6. The riser card of claim 5, wherein the power supply module comprises:
a battery fixed to the supporting board and supplying power to the high-speed signal card via the first circuit board; and
a battery backup unit fixed to the supporting board and electrically connected to the first circuit board and the battery.

7. An electronic apparatus comprising:
a casing;
a mainboard disposed in the casing
a riser card comprising:
a first circuit board having a first surface, a second surface, and a through hole communicating the first surface and the second surface;
a plurality of slots disposed spaced apart on the first surface;
a connection terminal for connecting to the mainboard; and
a fixing bracket fixed to the first circuit board and the casing; and
at least one high-speed signal card comprising a plurality of connecting portions, each of the connecting portions connecting to a corresponding slot of the riser card.

8. The electronic apparatus of claim 7, wherein the slots comprise a first slot and a second slot, the through hole is located between the first slot and the second slot, the connecting portions comprise a first connecting portion and a second connecting portion, and the first connecting portion and the second connecting portion respectively connect to the first slot and the second slot.

9. The electronic apparatus of claim 8, wherein the high-speed signal card further comprises:
a second circuit board, wherein the first connecting portion and the second connecting portion are located spaced apart at an edge of the second circuit board; and
a heat sink fixed to the second circuit board and extending from the edge of the second circuit board to a section between the first connecting portion and the second connecting portion,
wherein the heat sink is located between the slot and the second slot and partially accommodated in the through hole.

10. The electronic apparatus of claim 7, wherein the riser card further comprises a plurality of the slots disposed spaced apart on the first surface and respectively connected to a plurality of the high-speed signal cards.

11. The electronic apparatus of claim 7, wherein the riser card further comprises:
a supporting board fixed to the second surface; and
a power supply module fixed to the supporting board and supplying power to the high-speed signal card via the first circuit board.

12. The electronic apparatus of claim 11, wherein the power supply module comprises:
a battery fixed to the supporting board and supplying power to the high-speed signal card via the first circuit board; and
a battery backup unit fixed to the supporting board and electrically connected to the first circuit board and the battery.
